(19) United States
(12) Patent Application Publication
(10) Pub. No.: US 2026/0044085 A1
(43) Pub. Date: Feb. 12, 2026

(54) LINE SCANNING TEMPORALLY FOCUSED TWO-PHOTON LITHOGRAPHY SYSTEM

(71) Applicant: Massachusetts Institute of Technology, Cambridge, MA (US)

(72) Inventors: Edward Boyden, Chestnut Hill, MA (US); Daniel Oran, Cambridge, MA (US); Peter T. So, Cambridge, MA (US); Cheng Zheng, Cambridge, MA (US)

(73) Assignee: Massachusetts Institute of Technology, Cambridge, MA (US)

(21) Appl. No.: 19/115,878

(22) PCT Filed: Sep. 26, 2023
(86) PCT No.: PCT/US2023/075104

§ 371 Date: Mar. 27, 2025

Related U.S. Application Data
(60) Provisional application No. 63/377,439, filed on Sep. 28, 2022.

(51) Int. Cl. G03F 7/00; G02B 27/09; G02B 27/10; G02B 27/14; G03F 7/20

(52) U.S. Cl. CPC G03F 7/70375; G02B 27/0938; G02B 27/1086; G02B 27/141; G03F 7/2053; G03F 7/70041; G03F 7/7055

(57) ABSTRACT

The present invention presents improved systems and methods for performing multi-photon lithography. A line-scanning temporally focused two-photon lithography (LS-TFTPL) technique is capable of patterning three-dimensional structures with high throughput. An example LS-TFTPL system may include a pulsed laser, first optical components for expanding light pulses into an elongated or line cross section, a digital micromirror device for modulating the light pulses with a linear pattern and dispersing spectral components of the modulated light pulses, and second optical components for focusing the dispersed spectral components of the modulated light pulse at a line in or on a target material. The focused spectral components may alter the target material within selected voxels along the line, where the selected voxels spatially correspond to the linear pattern.

### RELATED APPLICATIONS

This application claims benefit under 35 U.S.C. § 119(e) of U.S. Provisional application Ser. No. 63/377,439 filed Sep. 28, 2022, the disclosure of which is incorporated by reference herein in its entirety.

### GOVERNMENT SUPPORT

This invention was made with Government support under Grant No. ROl EB024261 and U19 MH114821 awarded by the National Institutes of Health; under Grant No. DE-SC0021593 awarded by the Department of Energy (DOE); and under Grant No. N00014-17-1-2977 awarded by the Office of Naval Research (ONR). The Government has certain rights in the invention.

### FIELD OF THE INVENTION

The invention relates to lithographic techniques for modifying a target material, and more specifically to multi-photon lithography.

### BACKGROUND OF THE INVENTION

The miniaturization of structured materials has transformed the world, from the transistors enabling modern computing to the micromirror arrays in light projectors to the inertial measurement units in every drone, smartphone, and modern GPS. On the nano- and micron-scale, due to massive investment from the semiconductor industry, lithographic processing methods have been developed, including multi-photon lithography. However, these technologies are based on planar fabrication approaches, limiting products to two dimensions unless painstaking multiple exposure processes are used to build quasi-three-dimensional devices. Existing multi-photon lithography techniques include point-by-point and planar techniques. Point-to-point multi-photon lithography techniques may rely on mechanically scanning of a single excitation voxel, limiting throughput. Planar techniques are limited in their ability to create three-dimensional structures. As a result, there is need for high-throughput lithographic processes that can extensively pattern materials at the nanoscale in three dimensions.

### SUMMARY OF THE INVENTION

According to an aspect of the invention, a method of multi-photon lithography, is provided, the method including: (a) generating a first pulsed light beam having a spectral bandwidth; (b) expanding the first pulsed light beam to give the first pulsed light beam an elongated cross section; (c) modulating light pulses of the expanded first pulsed light beam to give one or more of the light pulses an independently selected linear pattern; (d) dispersing spectral components of the modulated light pulses; and (e) focusing the dispersed spectral components of the modulated light pulses at an independently selected line in an independently selected focal plane within a target material, wherein the focused spectral components alter the target material within independently selected voxels in the independently selected line, and the independently selected voxels are in spatial correspondence with the independently selected linear pattern. In some embodiments, the altering of the target material includes one or more of adding, removing, or transforming a component of the target material. In certain embodiments, the altering includes one or more of: photopolymerization, photo-induced conjugation, densification, ablation, sintering, melting, photodegradation, and dielectric breakdown of the component of the target material. In certain embodiments, the component of the target material includes one or more of: a gel, a glass, a chromophore, a liquid, a gas, plasma, a nanomaterial, a metal, a conductor, a solid, a semiconductor, and a dielectric. In some embodiments, the liquid includes one or more of water and dimethyl sulfoxide (DMSO). In some embodiments, the method also includes generating a second pulsed light beam and expanding, modulating, dispersing, and focusing the generated second pulsed light beam as in steps (b)-(e), respectively. In certain embodiments, the independently selected linear pattern of the modulated expanded second pulsed light beam is different from the independently selected linear pattern of the modulated expanded first pulsed light beam. In some embodiments, the dispersed spectral components of the first and second pulsed light beams are focused at different independently selected lines. In some embodiments, the dispersed spectral components of the first and second pulsed light beams are focused at independently selected lines in different focal planes within the target material. In some embodiments, the method also includes directing the first pulsed light beam to a movable reflective component, wherein the movable reflective component causes the dispersed spectral components of the first pulsed light beam to focus at a first independently selected line in the focal plane; adjusting the movable reflective component; and directing the second pulsed light beam to the adjusted movable reflective component, wherein the adjusted movable reflective component causes the dispersed spectral components of the second pulsed light beam to focus at a second independently selected line in the focal plane. In certain embodiments, modulating the light pulses and dispersing the spectral components of the modulated light pulses are accomplished using a digital micromirror device. In certain embodiments, the method also includes receiving, at a dichroic mirror, light originating from the specimen; and directing, using the dichroic mirror, the light to a camera. In some embodiments, expanding the first pulsed light beam includes: directing the first pulsed light beam through a first cylindrical lens and a second cylindrical lens, the first and second cylindrical lenses configured to give the first pulsed light beam an elliptical cross section; directing the elliptical first optical pulse through a first spherical lens and a second spherical lens to transform the elliptical cross section into an expanded elliptical cross section; and directing the expanded elliptical first optical pulse to a third cylindrical lens to transform the expanded elliptical cross section into the elongated cross section. In some embodiments, the method also includes shrinking the target material. In certain embodiments, the shrinking includes an Imp/Fab method.

According to another aspect of the invention, a method of multi-photon lithography is provided, the method including: (a) generating a first pulsed light beam having a spectral bandwidth; (b) expanding the first pulsed light beam to give the first pulsed light beam an elongated cross section; (c) splitting the expanded first pulsed light beam into a structured pattern of expanded pulsed light beams; (d) modulating light pulses of the structured pattern of expanded pulsed light beams to give the light pulses independently selected linear patterns; (e) dispersing spectral components of the modulated light pulses; and (f) focusing the dispersed spectral components of the modulated light pulses at independently selected lines in an independently selected focal plane within a target material, wherein the focused spectral components alter the target material within independently selected voxels in the independently selected lines, and the independently selected voxels are in spatial correspondence with the independently selected linear patterns. In some embodiments, the altering of the target material includes one or more of adding, removing, or transforming a component of the target material. In some embodiments, the altering includes one or more of: photopolymerization, photo-induced conjugation, densification, ablation, sintering, melting, photodegradation, and dielectric breakdown of the component of the target material. In certain embodiments, the component of the target material includes one or more of: a gel, a glass, a chromophore, a liquid, a gas, plasma, a nanomaterial, a metal, a conductor, a solid, a semiconductor, and a dielectric. In some embodiments, the liquid includes one or more of water and dimethyl sulfoxide (DMSO). In some embodiments, modulating the light pulses and dispersing the spectral components of the modulated light pulses are accomplished using a digital micromirror device. In certain embodiments, the method also includes receiving, at a dichroic mirror, light originating from the specimen; and directing, using the dichroic mirror, the light to a camera. In certain embodiments, expanding the first pulsed light beam includes: directing the first pulsed light beam through a first cylindrical lens and a second cylindrical lens, the first and second cylindrical lenses configured to give the first pulsed light beam an elliptical cross section; directing the elliptical first optical pulse through a first spherical lens and a second spherical lens to transform the elliptical cross section into an expanded elliptical cross section; and directing the expanded elliptical first optical pulse to a third cylindrical lens to transform the expanded elliptical cross section into the elongated cross section. In some embodiments, the method also includes shrinking the target material. In certain embodiments, the shrinking includes an Imp/Fab method.

According to another aspect of the invention, a system is provide, the system including: an optical pulse generator configured to generate a first pulsed light beam having a spectral bandwidth; at least a first optical element configured to expand the first pulsed light beam to give the first pulsed light beam an elongated cross section; a movable reflective component configured to direct the expanded first pulsed light beam along a first axis; a digital micromirror device (DMD) configured to: modulate light pulses of the expanded first pulsed light beam to give the to give one or more of the light pulses an independently selected linear pattern, and disperse spectral components of the modulated light pulses; and at least a second optical component configured to focus the dispersed spectral components of the modulated light pulses at an independently selected line in an independently selected focal plane within a target material, wherein the focused spectral components alter the target material within independently selected voxels in the independently selected line, and the independently selected voxels are in spatial correspondence with the independently selected linear pattern. In some embodiments, the system also includes: a diffractive optical element configured to split the expanded first pulsed light beam into a structured pattern of expanded pulsed light beams, wherein: the DMD is configured to modulate light pulses of the structured pattern of expanded pulsed light beams to give the light pulses independently selected linear patterns, the DMD is configured to disperse spectral components of the modulated light pulses, and the second optical component is configured to focus the dispersed spectral components of the modulated light pulses at independently selected lines in an independently selected focal plane within a target material, wherein the focused spectral components alter the target material within independently selected voxels in the independently selected lines, and the independently selected voxels are in spatial correspondence with the independently selected linear patterns. In some embodiments, the movable reflective component is a galvanometric scanner. In certain embodiments, the system also includes a camera configured to monitor a lithographic process within the target material; and a dichroic mirror configured to direct light originating from the target material towards the camera. In some embodiments, the at least first optical element includes: a first cylindrical lens and a second cylindrical lens, the first and second cylindrical lenses configured to expand the first optical pulse to give the first optical pulse an elliptical cross section; a first spherical lens and a second spherical lens configured to transform the elliptical cross section into an expanded elliptical cross section; and a third cylindrical lens configured to transform the expanded elliptical cross section into an elongated cross section focused on the DMD. In certain embodiments, the system also includes one or more additional optical components. In some embodiments, the system also includes one or more of: a beam shaper optical component, a spatial light modulator, and a deformable mirror. In certain embodiments, the beam shaper optical component includes a flat top beam shaper.

According to another aspect of the invention, a method of patterning on or in a target material is provided, the method including preparing a patterned target material using an embodiment of any aforementioned method. In some embodiments, the method also includes shrinking the patterned target material. In certain embodiments, the shrinking includes an ImpFab method.

### BRIEF DESCRIPTION OF THE DRAWINGS

FIG. 1 provides a schematic diagram showing an embodiment of a line scanning temporal focusing two-photon lithography (LS-TFTPL) system. CL refers to a cylindrical lens, L are spherical lenses, DOE is a diffractive optical element, DM is a dichroic mirror, OL is the objective lens and TL is a tube lens. A target material is shown with grid pattern at the far right.

FIG. 2A-C provides a photographic image and graphs showing resolution characterization of the LS-TFTPL system using 200 nm fluorescent beads. FIG. 2A shows an illustrative image of the 200 nm beads taken on an LS-TFTPL system. FIG. 2B shows a graph of lateral fluorescence intensity profile. FIG. 2C is a graph showing axial fluorescence.

FIG. 3A-B provides a demonstration of large volume, high aspect ratio patterning. FIG. 3A is a 1,836 μm by 333 μm (1.1 mm³) array of 20 micron diameter columns, top view (i) and side view (ii). The patterned pitch of the pillar array is 108 μm. FIG. 3B is a demonstration of fully patterned regions and high-aspect-ratio 3 micro thick and 300-micron tall lines, top view (i) and side view (ii).

FIG. 4 is a schematic diagram of a line-scan temporal focusing TPL system. LAS is the laser. L1, L2, L3, are relay lenses. DOE is a diffractive optical element. CL is a cylindrical lens. DMD is a digital mirror device. OL is the objective lens. D2NN represents the specimen space.

FIG. 5 is a schematic demonstrating principle of generalized phase contrast. Phase contrast filter provides a relative phase shift to the light going through the inner circle (low frequency component of the light) vs high frequency components of the light going through the outer annulus.

FIG. 6A-C provides graphs demonstrating results of simulation of phase-contrast pattern generation. FIG. 6A is a graph showing the phase-only input image, FIG. 6B is a graph showing the final normalized intensity distribution. FIG. 6C is a graph of a 1-D demonstration of the power advantage of generalizing contrast-patterning approach. One-micron objects are randomly distributed in the image ( 1/10 fill factor). For these objects, the two-photon excitation efficiency can be 60-70 times higher than the intensity level obtained from turning on a MEMS mirror (normalized to 1).

FIG. 7A-B provides schematic diagrams with FIG. 7A showing wide-field off-axis quantitative phase microscopy, and FIG. 7B showing angle-scan tomographic phase microscopy. A 2-D galvo or digital micromirror-based scanner is used to achieve back aperture scan pattern, which leads to spatial frequency coverage as also shown in FIG. 7B.

### DETAILED DESCRIPTION

Aspects of the invention include multi-photon lithography (TPL) fabrication systems and methods based, in part, on a line-scan approach. TPL is a process used for patterning a desired design (pattern of interest) onto a target material. The patterned target material may then be used for fabrication of miniaturized materials systems. Systems and methods of the invention can be used to prepare functional miniaturized systems and materials, which can be used in fields such as but not limited to: chemical analysis, biomedical research, electronics, pharmaceutical research, drug delivery, cell culture, neuronal activity monitoring, tissue engineering, etc.

The present disclosure describes a line scanning temporal focusing two-photon lithography (LS-TFTPL) system that improves on existing point-by-point and planar techniques. It has been determined that a line scanning approach used in an LS-TFTPL system of the invention is capable of achieving rapid fabrication speeds. Multi-photon lithography is a method that uses controlled laser scanning and modulation to create small (e.g., micro- and nano-scale) features in a photosensitive material, without photomasks or other complex optical systems. In some multi-photon techniques, a material that is transparent at the wavelength of the laser can be altered at a focal point of the laser by a multi-photon absorption process. Multi-photon absorption is a non-linear process that is several orders of magnitude weaker than linear absorption. The laser beam may be tightly focused to achieve light intensities sufficient to trigger the process within a small volume, thus allowing precision patterning at small scales.

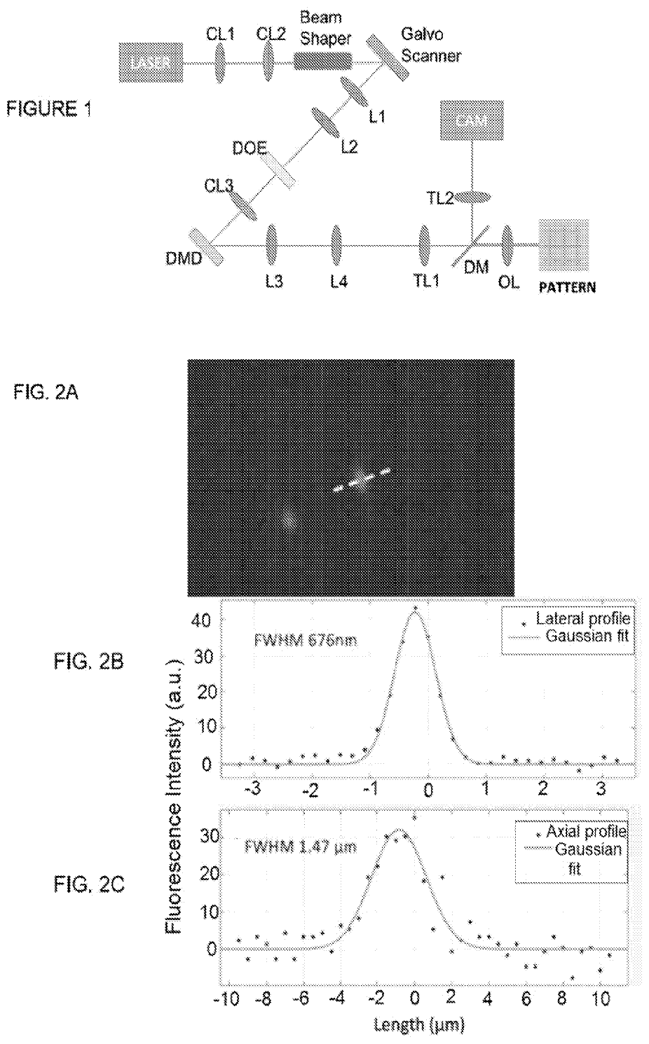

Certain embodiments of LS-TFTPL systems of the invention are capable of fabricating complex three-dimensional structures with higher throughput than previously achievable. FIG. 1 provides a schematic diagram of an embodiment of an LS-TFTPL system of the invention. The non-limiting example of an LS-TFTPL system shown in FIG. 1 includes components including, but not limited to: a laser, various lenses (CL1, CL2, L1, L2, etc.), a beam shaper, a galvo scanner, a diffractive optical element (“DOE”), a digital micro-mirror device (“DMD”), a camera, and a target material. The following describes aspects of an LS-TFTPL system of the invention and provides information about components that may be selected and included in certain embodiments of an LS-TFTPL system of the invention. Non-limiting examples of methods of using an LS-TFTPL system of the invention are also provided.

An LS-TFTPL system of the invention includes components such as an optical pulse generator, lenses, etc. As used herein in reference to LS-TFTPL system components, the term “independently selected” means each of the component types may be individually chosen for inclusion in an LS-TFTPL system. Thus, two or more independently selected components of the same type may be selected so each is the same as the others, each is different from the others, or some are the same and some different from the others. As a non-limiting example, an LS-TFTPL system may include 1, 2, 3, 4, 5, or more cylindrical lenses, spherical lenses, tube lenses, and objective lenses and the lenses are independently selected based on their individual functionality.

### LS-TFTPL System Components

The following describes various components that may be included in an LS-TFTPL system of the invention. It will be understood that additional components may also be included in certain embodiments.

### Optical Pulse Generators

LS-TFTPL systems of the invention include an optical pulse generator. In some embodiments of an LS-TFTPL system of the invention, an optical pulse generator is a laser (also known as a “pulsed laser”) configured to generate a pulsed light beam. A pulsed laser included in an embodiment of an LS-TFTPL system of the invention generates short duration optical pulses that have a broad spectral bandwidth relative to beams emitted by continuous wave lasers, which are generally monochromatic (e.g., having a narrow bandwidth). A spectral bandwidth of a laser utilized in an LS-TFTPL system of the invention can be leveraged to disperse and refocus the optical pulses on or within a target material with increased precision in the z-axis (e.g., a direction aligned with the optical axis, where the line onto which the spectral components is focused lies in the x-y plane).

A generated pulsed light beam may be of short duration and have a wide spectral bandwidth. In some embodiments of the invention, the duration of a light pulse is at least 10, 20, 30, 40, 50, 60, 70, 80, 90, 100, 110, 120, 130, 140, or 150 femtoseconds (fs). In some embodiments, the generated pulsed light been duration is in a range of from 10-20 fs, 10-50 fs, 10-100 fs, 10-150 fs, 20-50 fs, 20-100 fs, 20-150 fs, 40-150 fs, 50-80 fs, 50-100 fs, 50-150 fs, and/or 100-150 fs, inclusive of the ends of each range. In certain non-limiting embodiments of the invention light pulses, also referred to herein as “pulsed light beams” are emitted by the optical pulse generator at wavelengths, which include but are not limited to infrared, near-infrared, visible light, and ultraviolet wavelengths. In some embodiments, the spectral bandwidth is from 5-100 nm. In some embodiments, the spectral bandwidth is one or more of from 5-10 nm, 5-50 nm, 5-100 nm, 10-50 nm, 10-100 nm, 20-50 nm, 20-100 nm, 50-100 nm, 80-100 nm, and 90-100 nm, inclusive of the ends of the ranges. In some embodiments, a method of the invention is performed at between 800-1700 nm [near infrared (NIR); short-wave infrared (SWIR)]. In certain embodiments of systems and methods of the invention shorter wavelengths are used, a non-limiting example of which are wavelengths from ˜400-800 nm, which includes near-ultraviolet to visible light.

A non-limiting example of a laser that may be used in certain embodiments of an LS-TFTPL system of the invention, is a femtosecond pulsed laser that can emit an intensity of light sufficient for multi-photon lithography. A non-limiting example of a sufficient peak intensity of light for typical fluorophore is ˜1 TW/cm². In some embodiments, a laser included in an embodiment of a LS-TFTPL system of the invention is a regenerative amplifier pumped optical parametric amplifier; a non-limiting example of which is a Coherent Monaco and Opera-F system. In some embodiments of a LS-TFTPL system of the invention, the laser has a wavelength of 1040 nm and a pulse width of 350 fs. It will be understood that the systems and methods of the invention encompass various combinations of fluorophores and laser types, which can be selected based on the disclosure provided herein in conjunction with knowledge available in the art.

Another component that may be included in certain embodiments of an LS-TFTPL system of the invention is a component that increases the frequency of the laser. A non-limiting example of such a component is a frequency doubler, which can, in a non-limiting example, provide a 780 nm excitation wavelength with a ˜80 fs pulse width and a pulse energy of 2 μJ. Non-limiting examples of other components that may be independently selected and included in a system or used in method of the invention are a pulse compressor to reduce laser pulse width and fabrication efficiency; a fast shutter (or a modulated AOM/EOM) to gate or control the duty cycle of the beam; and a deformable mirror for aberration correction. It will be understood that the systems and methods of the invention encompass various combinations of components, which can be selected based on the disclosure provided herein in conjunction with knowledge available in the art.

Fabrication speed of an LS-TFTPL system of the invention may in some embodiments be proportional to the average power of the laser, and thus power loss from the laser may reduce fabrication speed. In some implementations, alternative lasers, a non-limiting example of which is a White Dwarf WD-800 laser (Class 5 Photonics, Hamburg, Germany) can be included in an LS-TFTPL system of the invention and can provide output at 800 nm with a pulse width of <10 fs and an average power of 4.5 W. It has been determined that fabrication speeds of an LS-TFTPL system of the invention depend, in part, on the power of the laser. As a non-limiting example, a fabrication speed of an embodiment of an LS-TFTPL laser can be increased by 2-10 times, 5-20 times, 10-30 times, 15-35 times, 20 to 40 times, 25-45 times, 30-50 times or more, by including relatively higher powered laser as an optical generator in the system. Based on the disclosure provided herein, one skilled in the art will understand how to utilize higher power lasers in embodiments of LS-TFTPL systems of the invention to increase fabrication speeds. In a non-limiting example, a WD-HE-800 laser having an average power of 8-10 W is used in an embodiment of an LS-TFTPL system of the invention. It will be understood that embodiments of systems and methods of the invention can include power ranges selected based in part, on the field of view and to reduce risk of boiling of a sample. It will be understood that the power of a laser included in an embodiment of a system and/or method of the invention can be selected based on the disclosure provided herein in conjunction with knowledge available in the art.

### Optical Components

Downstream from an optical pulse generator in an LS-TFTPL system of the invention, various optical components are positioned. Optical components in an LS-TFTPL system of the invention can be used to focus light generated by the optical pulse generator on a region of a target material to achieve a functional energy density within the target material. An LS-TFTPL system of the invention may include optical components capable of transforming a cross-section shape of a generated optical pulse from a circular or disc cross section to an elongated cross section. In some embodiments of an LS-TFTPL system of the invention, an elongated cross-section is an oblong cross section or an elliptical cross section. In certain embodiments of an LS-TFTPL system of the invention, an elongated cross section is a line.

Optical components used in certain embodiments of the invention may include 0, 1, 2, 3, 4, or more of a cylindrical lens (CL); 0. 1, 2, 3, 4, or more of a spherical lens (L); 0. 1, 2, 3, 4, or more of a tube lens (TL); and 0, 1, 2, 3, 4, or more of an objective lens (OL). Each of CL, L, TL and OL are known in the art and understood to have certain characteristics. For example, a CL can focus light into a line rather than a point; an L (also referred to in the art as a singlet) has curved surfaces that cause light that passes through to converge or diverge; a TL (also known in the art as a relay lens) is capable of taking a parallel optical beam coming down from an infinite objective and converging the parallel optical beam onto a sensor, material, and/or surface; and OLs are available in various magnification powers, such as but not limited to 4×, 10×, 20×, 40×, and 100× magnification, which may be referred to as “scanning”, “low power”, “high power”, and “oil immersion” lenses, respectively.

Certain embodiments of an LS-TFTPL system of the invention include one or more optical components for transforming a cross section of the pulsed light beam. For example, the laser may emit optical pulses having a round or disc cross section. Optical components may be included in the LS-TFTPL system to transform the pulsed light beam from the round cross section to an elongated cross section, which in some embodiments is a line. In some embodiments, cylindrical lenses are used to widen the pulsed light beam from a circular beam cross section to an elliptical beam cross section. In some embodiments, a galvo may be included to scan the widened pulsed light beam to scan a focal line across the target material. Further optical elements such as one or a plurality of spherical lenses may be included to expand the pulsed light beam. One or more additional cylindrical lenses may be included and focus the expanded, widened pulsed light beam into a thin line on the DMD. In some implementations, a focused line 1, 2, 3, 4, 5, 6, 7, 8, 9, 10, 11, 12, 13, 14, 15, 16, 17, 18, 19, or 20 mm length. In some implementations, the line may have a length similar to the width of a digital mirror or micromirror device (DMD) included in the LS-TFTPL system. The arrangement of optical components illustrated in FIG. 1 and described above herein are provided as an example only, and other embodiments may have different arrangements and components configured to transform the round cross section of the pulsed light beam into a line on the DMD. In various embodiments, more, fewer, and/or different optical components may be used. In addition, the galvo may be inserted at various points relative to the optical components.

Additional optical components that may be included in an LS-TFTPL system of the invention are components capable of manipulating the light pulses produced and emitted by the optical pulse generator. Non-limiting examples of such optical components include a movable reflective element and a digital mirror device (“DMD”). The term DMD is also used herein to refer to a digital micromirror device. A non-limiting example of a movable reflective element is a galvanometric scanner (“galvo”), which may include an electronically actuated mirror for directing a pulsed light beam along one or more axes. In some embodiments of a system of the invention a movable reflective element may scan a line across a target material to generate complex two- and three-dimensional patterns in the target material.

A DMD included in an embodiment of an LS-TFTPL system of the invention may provide one of more functions. In some embodiments of an LS-TFTPL system of the invention, a DMD component generates spectral dispersion and spatial patterns of light pulses. As a non-limiting example, a DMD included in an embodiment of an LS-TFTPL system of the invention is configured to modulate light pulses of a pulsed light beam to impart independently selected linear patterns on one or more of the light pulses. As used herein in reference to linear patterns the term “impart” means the DMD alters the pattern of a light pulse to be an independently selected linear pattern. As used herein in reference to a linear pattern of a light pulse, the term “independently selected” means that in instances in which there are two or more light pulses, the linear pattern of each of the two or more may be individually chosen and implemented. Thus, in instances in which there are two light pulses, the independently selected linear patterns of the two may be configured to be the same as each other or may be configured to be different from each other. Similarly, in embodiments of the invention with more than two light pulses modulated by a DMD, the independently selected linear light pulses may configured such that all are the same; each is different from the others; two or more are the same as each other; or two or more are different from each other as a result of their independent selection.

In some embodiments of an LS-TFTPL system of the invention a DMD is used to modulate one or more of: (a) a first light pulse to produce a first linear pattern, (b) a second light pulse to produce a second linear pattern, (c) a third light pulse to produce third linear pattern, and so on whereby the produced linear patters for (a), (b), and (c) are independently selected linear patterns. It will be understood that independent selection of linear patterns for a plurality of light pulses may result in all of the plurality being the same, each of the plurality being different from the others, or some of the plurality being the same and some being different from each other. As used herein the term, “plurality” means two or more. In some instances, a plurality means at least 2, 3, 4, 5, 6, 7, 8, 9, or 10. In some embodiments of systems and methods of the invention, a plurality is more than 10.

A DMD included in an embodiment of an LS-TFTPL system of the invention may serve as a diffraction grating (e.g., to disperse spectral components of the pulsed light beam) and/or as a pattern loader that can modulate optical pulses to achieve the desired patterns in the target material. A non-limiting example of a DMD that may be included in an LS-TFTPL system of the invention is a V-9001 by Vialux of Chemnitz, Germany. After dispersion of spectral components by a DMD, additional optical element such as one or more spherical lenses tube lenses may be used to relay the dispersed spectral components to an objective lens. In some embodiments of LS-TFTPL systems of the invention, focal lengths of lenses the system are selected for inclusion to fulfill determined criteria. A non-limiting example is selecting spherical lenses and a tube lens such that they result in the spectral components dispersed by the DMD to fill a back aperture of an objective lens OL. Filling the back aperture of the OL may allow full use of the numerical aperture of the OL in order to achieve close to or all of the theoretical resolution of the LS-TFTPL system. A second non-limiting example is selection of spherical lenses and tube lenses such that their use implements demagnification to map 3×3 elements of the DMD into one diffraction-limited location on a focal plane, a non-limiting example of which is on or in the target material. In some embodiments of LS-TFTPL systems, demagnification using lens selection is used to improve the output from the DMD. In a non-limiting example, a DMID in an embodiment of an LS-TFTPL system of the invention may have 7.6 μm pixel elements and a lateral dimension of ˜20 mm, and demagnification may be used to utilize the full spatial bandwidth product of the DMD.

In certain embodiments of an LS-TFTPL system of the invention, a DMD coupled to a diffraction grating is used to generate spectral dispersion of one or more light pulses and one or more independently selected linear patterns, also referred to herein as “spatial patterns.” In some embodiments of systems of the invention, the coupling of the DMD to a diffraction grating comprises use of lenses in a 4-f geometry. See for example: Park, J. K.; Rowlands, C. J.; So, P. T. C., Micromachines 2017, 8, 85; doi:10.3390/mi8030085. Some embodiments of systems and methods of the invention include a diffraction grating system. In certain embodiments of systems of the invention, a diffraction grating is a holographic diffraction grating. Certain embodiments of systems and methods of the invention include GRISM-based systems [see for example Dana, H. & S. Shoham, Opt. Lett. 37, 2913-2915 (2012).]

One or more additional optical components may be included in some embodiments of an LS-TFTPL system of the invention. A non-limiting example of an additional optical component that can be included is an optical component capable of focusing dispersed spectral components of light pulses emitted by the optical pulse generator of the system. Focusing optical component may be used to focus the spectral components on and/or in a target material, also referred to herein as “contacting” the target material with the focused spectral components. An LS-TFTPL system of the invention can be used to generate and focus spectral components on or in a target material to alter the target material contacted by the focused spectral components. Thus, an embodiment of a method of using an LS-TFTPL system of the invention comprises generating pulsed light beam(s), expanding the generated beam(s) to give the pulsed light beam(s) an elongated cross section, modulating the expanded pulsed light beam(s) to give the expanded light pulses independently selected linear pattern(s), dispersing spectral components of the modulated light pulses, and focusing the dispersed spectral components on or in a target material (also referred to herein as “contacting” the target material”), thereby altering the contacted target material.

In some embodiments of LS-TFTPL systems of the invention, an objective lens (OL) is used to focus dispersed spectral components of elongated and modulated light pulses on a line in a focal plane on and/or in a target material. In a non-limiting example, an OL included to focus dispersed spectral components is a water-immersion objective. In some embodiments, a focusing OL has a 0.95 NA, 2 mm working distance, and a millimeter size FOV. In some implementations, an OL having a greater working distance, non-limiting examples of which are a working distance 3 mm, 4 mm, 5 mm, 6 mm, 7 mm, 8 mm, 9 mm, 10 mm, or more, may be used to pattern structures extending further in the z-axis. In some embodiments the working distance of the OL is between 2 mm and 3 mm (inclusive); between 2 mm and 4 mm (inclusive), between 3 mm and 5 mm (inclusive); between 3 mm and 6 mm (inclusive); between 3 mm and 8 mm (inclusive); or between 4 mm and 8 mm (inclusive).

Additional components that may be included in an embodiment of an LS-TFTPL system of the invention include components that control patterning depth in the target material. For example, though not intended to be limiting, patterning depth may be controlled using a precision piezo controller and/or a motorized z-axis target material stage. Accordingly, the LS-TFTPL system may pattern large volumes (a non-limiting example of which is a pattern volume greater than 1 mm³) including structures having large aspect ratios. Non-limiting examples of aspect ratios are up to: 1:10, 1:100, 1:500, 1:1,000, 1:5,000, and 1:10,000. Certain embodiments of systems and methods of the invention have an aspect ratio of up to 1:10⁴.

Thus, certain embodiments of an LS-TFTPL system of the invention may achieve higher axial resolution for a given spectral bandwidth than previous methods. Furthermore, an LS-TFTPL system of the invention may maintain better axial resolution (e.g., in the z-direction) independent of the lateral pattern (e.g., in the x-y plane) to be fabricated. For example, embodiments of LS-TFTPL systems of the invention are capable of maintaining high axial (depth) resolution even for features having relatively large cross sections in the x-y plate.

Some embodiments of an LS-TFTPL system of the invention include an optional camera (“CAM”) configured to monitor a lithographic process within a target material. Such embodiments may include a dichroic mirror (“DM”) configured to direct light coming from the DMD to the target material, and direct light originating from the target material towards the camera. A tubular lens may, in combination with an objective lens OL, focus light from the target material on a light-sensitive component of the camera CAM. The camera and optics may be configured to reflectance images and/or fluorescence images of the target material.

Some embodiments of an LS-TFTPL system of the invention include a beam shaper optical component. Beam shapers are refractive or diffractive optical components capable of changing the intensity distribution of transmitted laser light. A beam shaper included in a system and/or method of the invention may be used to create a non-Gaussian irradiance profile of the laser beam. As is known in the art, a flat top beam shaper, which may also be referred to as a “top hat” beam shaper, is a refractive optical component capable of converting a Gaussian beam profile to flat top profile with high efficiency, resulting in a constant irradiance profile through the cross-section of the laser beam. In some embodiments, a beam shaper included in a system of the invention is a flat top beam shaper, a non-limiting example of which is an AdlOptica π Shaper Flat Top Beam Shaper by Edmund Optics® (Barrington, NJ). Non-limiting examples of additional optical components that may be included in certain embodiments of systems of the invention are a spatial light modulator and a deformable mirror. It will be understood that alternative commercially available or custom beam shaper optical components may be included in certain embodiments of systems of the invention.

Some embodiments of an LS-TFTPL system of the invention include an optional diffractive optical element (“DOE”). Diffractive optical elements are optical components having microstructure patterns configured to alter and control the phase of transmitted laser light. A DOE may be manufactured from various substrates including, but not limited to, plastics, fused silica, germanium, sapphire, and zinc selenide (ZnSe). The materials and microstructures used may depend on the wavelength of the laser in the LS-TFTPL system. In some implementations, a DOE may be a diffractive beam splitter. A diffractive beam splitter may split the pulsed light source into a one- or two-dimensional array of beams. In some embodiments of an LS-TFTPL system of the invention, a DOE is a diffractive pattern generator. A diffractive pattern generator may be used to create complex patterns in the target material. The DOE may split a pulsed light beam to yield a structured pattern of pulsed light beams. The DOE may be added as a beam splitter to enable simultaneous multiple line scanning, thereby increasing throughput of the LS-TFTPL system. In some embodiments, a DOE is included in an LS-TFTPL system at the joint focal plane of lenses such as L2 and CL3 (see FIG. 1 as a non-limiting example). The DOE may split optical pulses into multiple collimated beams. FIG. 1 illustrates a DOE inserted between the galvo and the DMD, in some embodiments of LS-TFTPL systems of the invention a DOE is inserted at other positions within the system; for example, between the laser and L1, or at various other positions between the laser and the DMD. The structured pattern of pulsed light beams may focus into multiple lines on the DMD. The DMD may then modulate and/or disperse spectral components of the pulsed light beams as described elsewhere herein.

### Target Material and Alteration

Certain embodiments of an LS-TFTPL system of the invention may be used to alter a selected target material. The term “selected” as used herein in reference to a target material means a material of interest to alter using focused spectral components generated using an embodiment of an LS-TFTPL system of the invention. In certain embodiments of methods and systems of the invention, a target material is altered by focused spectral components contacting the target material. As used herein, the term “altered” used in reference to a target material means one or more pre-contact properties or characteristics of the target material are changed by the contact. The term “pre-contact” as used herein in reference to a target material means the target material before it is contacted with focused spectral components. It will be understood that the term pre-contact can be used to describe a material before any instance of contact with focused spectral components. For example, if in an embodiment of a method of the invention, a target material is contacted one or more times with focused spectral components, the material may be referred to as “pre-contact” with respect to the material before each of the one or more contacts of the target material with focused spectral components. Thus, a target material can be contacted and altered at least 1, 2, 3, 4, 5, 6, 7, 8, 9, 10, 50, 100, 500, 1000 or more times by at least 1, 2, 3, 4, 5, 6, 7, 8, 9, 10, 50, 100, 500, 1000, or more contacts with focused spectral components of the invention. It will be understood that one alternation in a target material that results from a contact with focused spectral components may differ from an alteration in the target material that results from a different (e.g. prior or subsequent) contact with focused spectral components in a method of the invention. Thus, certain embodiments of methods of the invention comprising 2, 3, 4, 5, 6, 7, 8, 9, 10, or more contacts of a target material with focused spectral components may result in 2, 3, 4, 5, 6, 7, 8, 9, 10, or more of the same or different alterations in the target material.

In some embodiments of a system or method of the invention, a target material comprises a polymer. Non-limiting examples of polymers and copolymers that can be used in a target material in a system or method of the invention are: a polyacrylate (PA) polymer and an acrylamide and sodium acrylate copolymer, etc. In some embodiments a polymer or copolymer comprising target material is a hydrogel, also referred to herein as a gel. In some embodiments, a polymer or copolymer is selected for use in a system or method of the invention based in part on the capacity of the polymer or copolymer for reliable shrinkage, which reduces variance between fabrications. Non-limiting examples of class of polymers that may be used in certain embodiments of systems and methods of the invention are polyelectrolytes and photoresists/photo-resins.

In some embodiments of methods of the invention, a selected target material used in a method of the invention is a homogenous material. A homogenous material may also be referred to in the art as a “pure” material that has consistent characteristics throughout the original material. Contact of a homogeneous target material with focused spectral components may result in one or more physical and/or chemical alterations in the homogeneous target material, and produce a post-contact material that is no longer homogeneous. In certain embodiments of methods of the invention, a selected target material used in a method of the invention is a heterogeneous material, which may be referred to as a “mixed” material comprising two or more different components. Contacting a heterogeneous target material with focused spectral components may result in a post-contact material that differs physically and/or chemically from the initial heterogeneous target material. Non-limiting examples of target materials that may be utilized in embodiments of methods of the invention are a gel, a chromophore, a liquid, a solid, a gas, plasma, a nanomaterial, a metal, a conductor, a semiconductor, and/or a dielectric. A liquid may be water or dimethyl sulfoxide (DMSO). A non-limiting example of a gel that may be used in an embodiment of a system of the invention is a polyacrylate gel. A non-limiting example of a chromophore that may be used in an embodiment of a system of the invention is fluorescein. Non-limiting examples of a gas that may be used in an embodiment of a system of the invention is a nitrogen and oxygen gas. A non-limiting example of a plasma that may be used in an embodiment of a system of the invention is oxygen plasma. Non-limiting example of a nanomaterial that may be used in an embodiment of a system of the invention is a carbon nanomaterial, non-limiting examples of which are graphene, carbon nanohorns (CNH), and buckyballs. A non-limiting example of a metal that may be used in an embodiment of a system of the invention is silver. A non-limiting example of a semiconductor that may be used in an embodiment of a system of the invention is silicon. A non-limiting example of a dielectric that may be used in an embodiment of a system of the invention is a silicon dioxide.

An alteration of a selected target material resulting from contact by focused spectral components in a method of the invention may include one or more of a physical and chemical alteration of the material. Non-limiting examples of types of alterations that may be produced by contacting a target material with a focused spectral component are addition, removal, and/or transformation of one or more components or characteristics of the target material. Non-limiting examples of physical and/or chemical changes to a target material that can be produced using certain embodiments of an LS-TFTPL method of the invention are photopolymerization, photo-induced conjugation, densification, ablation, sintering, melting, photodegradation, and dielectric breakdown of one or more components of the target material.

Some embodiments of systems and methods of the invention combine LS-TFTPL and ImpFab methods, permitting agents to be patterned onto or into a target material. A chromophore is a non-limiting example of an agent that can be patterned onto or into a target material. Patterning methods are illustrated herein at least in Example 6 and FIG. 5, which demonstrate use of an embodiment of a systema of the invention in which fluorescence of deposited Streptavidin568-nanogold conjugates patterned using chromophores was determined. Examples of chromophores that may be used in methods of the invention, include but are not limited to: Fluoresceinyl Glycine Amide (FGA), Alexa546-cadaverine, and Sulfo-Cy3-amine. Those skilled in the art will recognize additional agents suitable to be patterned on or into a target material using an embodiment of a system or method of the invention.

In a non-limiting example, LS-TFTPL and ImpFab methods of the invention can pattern chromophores onto a polyelectrolyte gel scaffold with multiphoton lithography at the diffraction limit. Agents, such as, but not limited to chromophores, may act as covalent chemical anchors carrying reactive sites that can be utilized for volumetric deposition into the target material, a non-limiting example of which is a gel scaffold.

Methods and systems of the invention may also include depositing functional agents including, but not limited to, high refractive index (HRI) dielectrics onto or throughout a patterned volume in a target material, a non-limited example of which is a swollen gel. Subsequently, solvent may be removed using a combination of salt, acid, and/or evaporation to shrink the scaffold laterally, resulting in densification of the deposited material, and a reduction in feature size can attain resolution; while still-pattern refractive index changes throughout a volume using sub 100 nm features. In some embodiments the amount of scaffold shrinkage is up to or equal to 1×, 2×, 3×, 4×, 5×, 6×, 7×, 8×, 9×, 10×, 11×, 12×, 13×, 14×, 15×, 16×, 17×, 18×, 19×, 20×, 21×, 22×, 23×, 24×, 25×, 26×, 27×, 28×, 29×, 30×, 31×, 32×, 33×, 34×, 35×, 36×, 37×, 38×, 39×, 40×, 41×, 42×, 43×, 44×, 45×, 46×, 47×, 48×, 49×, 50× or more. In some embodiments of systems and methods of the invention, densification of up to or equal to 2-fold, 10-fold, 25-fold, 50-fold, 75-fold, 100-fold, 200-fold, 300-fold, 400-fold, 500-fold, 6-fold, 700-fold, 800-fold, 900-fold, 1000-fold, 1500-fold, 2500-fold, 5000-fold, 10,000-fold, 25,000-fold, 50,000-fold, 75,000-fold, 100,000-fold, 125,000-fold or more. In some embodiments of systems and methods of the invention, the attained densification is between one or more of: 10-fold and 100-fold, 50-fold and 200-fold, 100-fold and 500-fold, 100-fold and 1000-fold, or 500-fold and 1,500-fold, 2-fold and 5,000-fold, 2-fold and 10,000 fold, 2-fold and 25,000-fold, 2-fold and 100,000-fold, and 2-fold and 50³-fold. In some embodiments of systems and methods of the invention the resolution attained is at least or equal to 3 nm, 4 nm, 5 nm, 6 nm, 7 nm, 8 nm, 9 nm, 10 nm, 20 nm, 30 nm, 40 nm, 50 nm, 60 nm 70 nm, 80 nm, 90 nm, 100 nm, 1 μm, 5 μm, 10 μm, 15 μm, 20 μm, 25 μm, 30 μm, 35 μm, 40 μm, 45 μm, 50 μm, 55 μm, 60 μm, 65 μm, 70 μm, 75 μm, 80 μm, 85 μm, 90 μm, 95 μm, and 100 μm, including each value within the range.

In some instances, a target material is treated before and/or after subjecting the target material to an LS-TFTPL method of the invention. In a non-limiting example, an LS-TFTPL system of the invention may be used in an implosion fabrication (ImpFab) process in which ImpFab is used to pattern a complex three-dimensional structure using multi-photon lithography, and followed by use of chemical means to shrink the resulting structure. Additional details are provided herein in Examples 12-14.

### Combinations and Certain Methods of Use

Existing multi-photon techniques are further limited to polymeric materials. Thus, in some implementations, LS-TFTPL techniques described herein may be combined with Implosion Fabrication processes to separate lithography steps from material deposition steps, thereby allowing for an extremely wide array of materials to be patterned. For example, the LS-TFTPL system may create a latent three-dimensional pattern in a swollen polyelectrolyte hydrogel containing chromophores. The LS-TFTPL process may alter the chromophores to cause a reaction that creates reactive group sites within selected voxels. Functional materials may then be deposited into the target material. The functional materials (e.g., metal, semiconductor, and/or other nano-materials) may attach to the reactive group sites. The polyelectrolyte hydrogel may then be shrunk (e.g., through exposure to an acid) to increase resolution and densification of the functional material. Combined with the ultra-high throughput of LS-TFTPL, this ultimately leads to the ability to quickly pattern cubic millimeter scale volumes with 50 nm resolution arbitrarily in three dimensions with a wide choice of potential materials.

As described herein, an LS-TFTPL system of the invention can be used in fabrication methods to alter a target material. For example, spectral components of a modulated light pulse generated by an optical pulse generator of an LS-TFTPL system of the invention can be focused on or within a target material in a manner such that the contact alters the target material. In some embodiments, the spectral components are focused on a line on or in the target material. The shape of the region of contact on or within the target material results from the shape of the focused spectral components that contact the target material. For example, though not intended to be limiting, spectral components that are focused along a line on or in a target material result in a line of contact on or in the target material. In some embodiments of methods of the invention, a contacted region of the target material may spatially correspond to the linear pattern of the light pulses that are dispersed and focused on or in the target material. The target material may be altered by the focused spectral components within selected voxels along the contacted line, and in certain embodiments, the selected voxels are in spatial correspondence with the independently selected linear pattern of the modulated light pulses. In a non-limiting example, focusing spectral components along a line on or in a target material alters the target material in a pattern that spatially corresponds to the linear pattern of the focused spectral components. In this manner, an optical pulse may impart the linear pattern on a line on or in the target material.

Methods of the invention that combine ImpFab with LS-TFTPL techniques improve fabrication compared to previous point-by-point two-photon lithography approaches, particularly with regard to throughput. Systems and methods of the invention provide a novel fabrication approach based on temporal focusing on a line-scanning geometry, which has been able to achieve identical 3D resolution as point scanning while improving upon the speed of state of the art full-field temporal focusing by more than two orders of magnitude⁷⁻⁹. Combined with lmpFab, a significantly larger range of spatial resolution and device dimensions has now been achieved. Methods and systems of LS-TFTPL/ImpFab as set forth herein enable efficient on-demand prototyping and manufacturing of complex 3D nano-featured components.

Certain embodiments of methods and systems of the invention utilize an LS-TFTPL/ImpFab system, which has several advantages over both traditional TPL and TFTPL. First, certain embodiments of methods and systems of the invention provide higher throughput than prior TFTPL methods. In some embodiments, systems and methods of the invention are at least 25, 50, 75, 100, 125, 150, 175 or 200 times higher throughput than the prior TFTPL methods⁶. In addition, certain methods and systems of the invention improve the achievable resolution of lithography by approximately 3-fold laterally after shrinkage, reaching the resolutions needed for photonics manufacturing. Third, certain embodiments of methods and systems of the invention eliminate issues resulting from photopolymerization by patterning chromophores directly into a scaffold. Fourth, certain embodiments of methods and systems of the invention enable the patterning of any geometry and gradients of material. Fifth, certain embodiments of methods and systems of the invention increase the working distance compared to prior methods such as TFTPL. In a non-limiting example, in some embodiments of systems and methods of the invention, the inclusion and use of a water/glycerol immersion objective increases the working distance by 4-40 times over prior TFTPL methods. Sixth, certain embodiments of methods and systems of the invention achieve low enough energy/voxel levels to achieve ultrafast throughput with a commercial femto-second laser.

A combination of an LS-TFTPL and ImpFab in systems and methods of the invention is well suited for building Deep Diffractive Neural Networks (D2NN). D2NN fabrication may require patterning of refractive index features with tens of nanometer resolution using a lasers having wavelengths in the visible and NIR spectral regions. Further, LS-TFTPL systems of the invention can be used for fabrication techniques with 3D capability thereby reducing or eliminating alignment error between neuron layers.

The present invention will be better understood in connection with the following Examples. However, it should be understood that these examples are for illustrative purposes only and are not meant to limit the scope of the invention. Various changes and modifications will be apparent to those skilled in the art and such changes and modifications including, without limitation, those relating to the formulations and/or methods of the invention may be made without departing from the spirit of the invention and the scope of the appended claims.

### EXAMPLES

### Example 1

### Line Scanning-Temporal Focusing Two-Photon Lithography (LS-TFTPL)

A LS-TFTPL system capable of patterning chromophores in gels for implosion fabrication (ImpFab) has been built and tested. A schematic of an embodiment of an LS-TFTPL system design is shown in FIG. 1. LASER is a regenerative amplifier-OPA system (Coherent Monaco-Opera) with central wavelength of 780 nm and pulse energy of 2 μJ, pulse width of 80 fs. The excitation is shaped from a circular beam into an elliptical beam by two cylindrical lenses, CL1 and CL2, and relayed to a galvometric scanner (galvo).

After the scanning mirror, the excitation beam was further expanded by spherical lenses L1 and L2, and focused by cylindrical lens, CL3, into a thin line of ˜10 mm in length on the digital micromirror device, DMD (Vialux V-9001). The DMD served efficiently both as a diffraction grating that dispersed the spectral component of the light and as a pattern loader that modulated each individual line to achieve the designed patterns in specimen volume. The focal lengths of L3, L4 and TL1 were chosen according to two criteria:

1. The dispersion of laser spectrum caused by DMD fill the objective lens back aperture to result in full use of the numerical aperture (NA) of the objective in order to achieve the expected theoretical resolution.

2. Because the DMD had 7.6 μm pixel element with a lateral dimension of −20 mm, there was no commercial lens that could fully utilize the full spatial bandwidth product of this DMD. Therefore, a demagnification of the system was implemented that mapped 3×3 elements on the DMD into one diffraction-limited location on the specimen plane.

The objective lens (OL) was a water immersion objective with 0.95 NA, 2 mm working distance, and a millimeter size FOV. A dichroic mirror, DM, was added to direct the emitted fluorescence during lithographic process to TL2 and camera, CAM, for real-time monitoring of the process. An optional diffraction optical element (DOE) was added at the joint focal plane of L2 and CL3 as a beam splitter to enable simultaneous multiple line scanning.

### Example 2

The diffraction-limited lateral and axial resolution of the system were characterized using fluorescent beads (FIG. 2A-C). A lateral resolution of 676 nm and an axial resolution of 1.47 μm were measured. It was observed that smaller features appear to require higher power/longer exposures in order to pattern to an equivalent degree to larger features. This was also observed by Saha et al. [Saha, S. K. et al. Science (80). 366, 105-109 (2019)], who showed that it was not a result of changing DMD grating efficiency, and instead “the size-dependent writing threshold behavior that is observed for lines wider than the diffraction-limited spot size is likely caused by the diffusion-reaction kinetics of the photo-polymerization process. For thinner lines, radicals generated in the illuminated regions could be rapidly quenched by the inhibitors diffusing in from the surrounding region. This radical quenching is suppressed when a large area was illuminated at once.” It was expected that it also involved radical formation, and thus would be similarly susceptible to radical quenching by diffusing inhibitors. Saha and coworkers compensated for this density-dependent patterning threshold by splitting a frame into two sequential patterning sequences: first the entire structure with a fast exposure, and then only the less dense regions for a longer exposure.

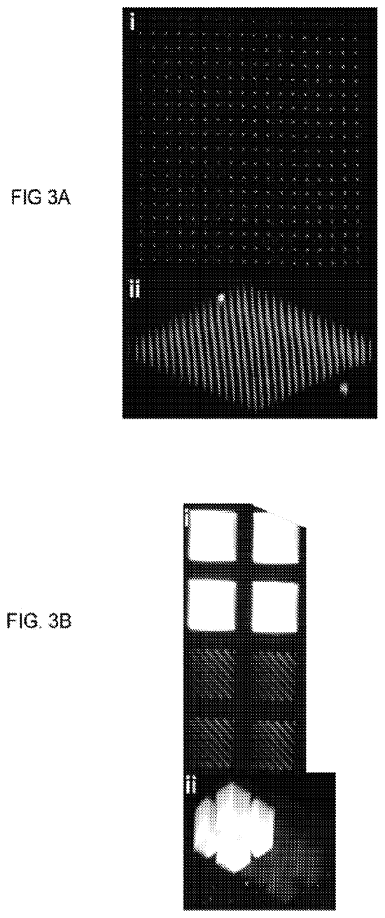

Studies were performed and results demonstrated the LS-TFTPL was easily able to pattern large (>1 mm³) volumes and created high aspect ratio (1:100) structures (FIG. 3A-B). A 1,836 μm by 1,836 μm by 333 tm (1.1 mm³) array of 20-micron diameter columns were patterned. In addition, studies were performed in which patterned arrays of 3 micron wide, 300 micron tall (1:100 aspect ratio) lines. The current pattering depth is limited by the range of the z-axis piezo controller, and is far from the objective's full working distance of 2 mm.

### Example 3

The LS-TFTPL system is prepared in which a motorized Z-axis specimen stage is used in addition to the precision piezo (see examples 1 and 2), allowing utilization of a full 8 mm working distance objective. Achieving aspect ratios of this magnitude and resolution constitutes a unique capability that cannot be achieved by any other top down nanofabrication method.

### Example 4

Demonstration of ImpFab with Line-Scan TFTPL

A TPL fabrication method based on a line-scan approach is prepared. Instead of full-field illumination, it has long been known that line-scan temporal focusing has nearly identical 3D resolution as point-scan two-photon excitation [Tal, E., et al., Optics letters 30, 1686-1688 (2005); Durst, M. E., et al., Optics express 14, 12243-12254 (2006); and Xue, Y. et al. Optica 6, 76-83 (2019)]. It has been determined that a line scanning approach can achieve similar speeds as widefield illumination. TPL speed is not just limited by the degree of parallelization but instead by two other factors. The first factor is the maximum laser pulse energy, Eₘₐₓ (typically on the nJ scale) that can be applied at each location; this factor is limited by the saturation of the photo-reactive molecules. As a rule-of-thumb, two-photon excitation axial resolution will degrade quickly near saturation when single pulse excitation probability (Pᵣ) is higher than 10% for photo-reactive molecules [Nagy, A., et al., Journal of Biomedical Optics 10, 044015 (2005)]. Given the pulse energy at each diffraction limited location has a maximum value, fabrication speed can only be improved with parallelization. However, the degree of parallelization is limited because all mediums absorbs light and thermal overrun, boiling, ultimately limits the maximum power, Pₘₐₓ, that can be deployed. Specifically, the number of fabricated volumes, n, patterned per second can be expressed as:

$$n = {n}_{p} {f}_{r} = \frac{{P}_{m ax}}{{E}_{m ax}} \qquad ( 1 )$$

where nₚ is the number of fabricated volumes for each laser pulse and fᵣ is the pulse repetition rate (in Hz) of the laser. Because Eₘₐₓ is a constant for given photo-active molecules (and laser pulse width), the maximum number of fabrication locations per second depends only on Pₘₐₓ (in Watts), the total average power incident on the sample limited by the boiling of the specimen. Therefore, fabrication can be performed one plane at a time or by a fast scanning line as long as the same average power is used.

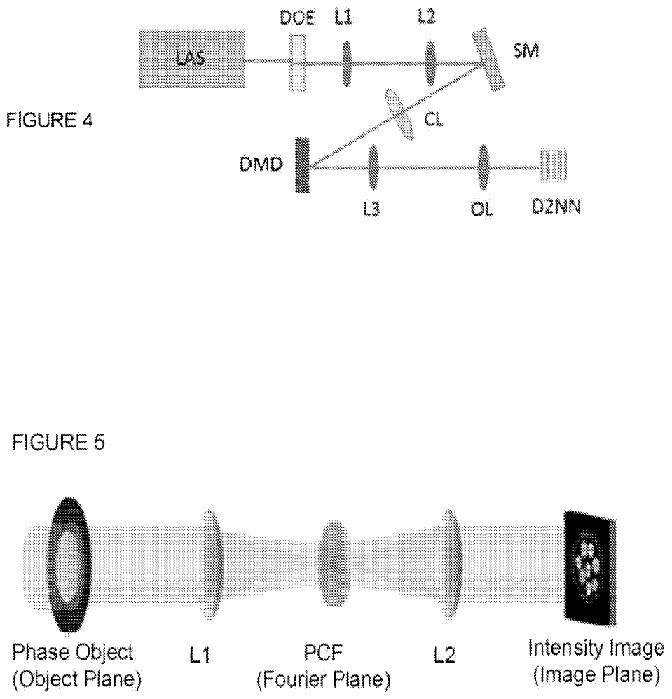

Given these considerations, a line-scan TFTPL system (FIG. 4) is implemented. Femtosecond pulses are split into multiple collimated beams by a diffractive optical element (DOE); scanning multiple lines, which further improves speed. The multiple beam is relayed to a scanner mirror, SM, via relay lenses L1 and L2. After the scanning mirror, these beams are expanded into multiple lines on to a digital mirror device, DMD, via a cylindrical lens, CL. The DMD first serve as a grating element that disperse the spectral component along the optical axis. The different spectral components recombine at the focal plane within the fabrication volume but are separated almost elsewhere ensuring that the temporal pulse width is broadened except at the focal plane where two-photon excitation is maximized. The DMD further serves to pattern each individual line. The lens, L3, and the objective, OL then relay these beamlets onto the specimen volume represented by the Deep Diffractive Neural Networks (D2NN). Further, software is developed using a Matlab (Mathworks, MA) graphical user interface. The software interfaces with the design toolbox, (see details elsewhere herein).

With the design specification, the design is converted into 2D slices; each 2D slice is divided into smaller 2D areas equal to the field of view (FOV) of the microscope objective lens used. The designed instrument has FOV of about 0.5×0.5 mm². Therefore, the fabrication of a 1 mm² optical component is completed by montaging 400 2D areas. The specimen is translated along the optical axis to enable fabrication of 3D structures.

With the construction of a line-scan TPL system, fabrication speed and resolution are evaluated as a function of key system parameters. From equation (1), the key parameters that control fabrication speed are Eₘₐₓ and Pₘₐₓ. The relationship between excitation probability and pulse energy can be written as:

$${P}_{r} ∼ \frac{{δ ( NA )}^{4} {E}_{m ax}^{2}}{τ} \qquad ( 2 )$$

where δ is the two-photon cross section of the chromophore, NA is the numerical aperture of the excitation objective, and τ is the laser pulse width. As discussed previously, because the optimal excitation probability should be 10% to avoid saturation, P_{τ} is a constant. Therefore,

$${E}_{m ax} ∼ \frac{1}{{( NA )}^{2}} \sqrt{\frac{τ}{δ}} \qquad ( 3 )$$

From equation (1) fabrication speed is maximized when Eₘₐₓ is minimized. From equation (3), this condition translates to maximizing chromophore two-photon cross section and minimize laser pulse width. The laser pulse width may be controlled by the addition of a compressor that regulates the dispersion of femtosecond pulses [Choi, H. & So, P. T. Scientific Reports 4, 6626, doi:10.1038/srep06626 (2014)]. The pulse width is varied over a range from about 100 fs to 1 ps and the quadratic dependence on fabrication rate is verified. The maximum laser average power Pₘₐₓ is varied by changing laser pulse repetition rate fᵣ. Studies demonstrate that fabrication speed increases linearly with increasing repetition rate.

Fabrication resolution [and Eₘₐₓ, see equation (3)] is a function of the numerical aperture of the excitation objective. In general, resolution and fabrication speed are both optimized when numerical aperture is maximized. Commercial water immersion objective can attain a numerical aperture of about 1.0 while having a millimeter size field of view. The resolution of patterns generated are compared with the theoretical estimates given the numerical aperture used and diffraction theory. Fabrication speed and resolution likely behave near theoretical limit at the center of the field of view but may be degraded at the edge where aberration tends to be significant. This degradation is characterized and a usable field of view for this TFTPL system is empirically established. Writing multiple lines in parallel improves speed but interference between these lines can also lower resolution [Park, J. K., et al., Micromachines (Basel) 8, doi:10.3390/mi8030085 (2017)].

### Example 5

ImpFab with Line-Scan Temporal Focusing Two-Photon Excitation

In some studies an existing regenerative amplifier pumped optical parametric amplifier (Coherent Monaco and Opera-F system) is used. The wavelength of Monaco is fixed at 1040 nm with a pulse width of 350 fs. Although the use of Opera-F optical parametric amplifier coupled with a frequency doubler provides the optimal 800 nm excitation wavelength at ˜150 fs pulse width, the conversion process is lossy and the output average power drops from 4 W down to about 400 mW. As discussed elsewhere herein, fabrication speed is directly proportional to average power and this lossy conversion proportionally reduces fabrication speed. Therefore, while this laser is sufficient to validate the line-scan TFTPL design, the demonstration of optimal fabrication speed utilizes a more suitable laser; such as, but not limited to a White Dwarf WD-800 (Class 5 Photonics), which can provide output at 800 nm, with less than 10 fs pulse width and an average power of 4.5 W. Optimizing the line-scan TPL system with this laser results in a speed improvement of about 30-50 times, from both increasing average power and decreasing pulse width. Even more powerful systems with average power up to 8-10 W are available for use in systems and methods of the invention (a non-limiting example of which is: White Dwarf HE WD-HE-800 from Class 5 Photonics) that can further increase fabrication speed.

This work is performed, in part, to evaluate and install an optimized laser system into the line-scan TFTPL system. The work includes ensuring the sub 1000 fs pulses are transmitted through the intermediate optical components into the specimen without broadening. Second and higher order dispersion effects are much more severe when pulse width gets shorter. These dispersion effects are managed by optimizing choices of optical components used in the TFTPL system. Quadratic, and if necessary, high order dispersion compensation components are added to ensure the desired short pulse width is maintained. In addition to pulse width optimization, the maximum average power that can be used without thermal overrun in the specimen is also evaluated. Thermal overrun is a function several parameters of the system design such the average power, pulse repetition rate, exposure area size, and fabrication chemistry. Studies are performed to systematically explore this parameter space to identify the optimal fabrication conditions in conjunction with chemistry optimization. Finally, as previously discussed, aberration is always present in an optical system and can degrade both fabrication speed and resolution. Studies are performed with the prepared system to determine aberration minimization strategies to further optimize this TPL system including the use of adaptive optical control.

### Example 6

### Multiphoton Holographic ImpFab as Complementary Fabrication Approach

The line-scan TFTPL is a major improvement over point scanning approach for 3D fabrication speed. However, because it uses a MEMS mirror, its efficiency depends on the patterns to be written. For patterns that are very sparse, the MEMS mirror approach may be suboptimal as the light from the off-pixels are just lost. Instead, studies are performed using a method called generalized phase contrast, first developed by Gluckstad and co-workers [Rodrigo, P. J., et al., OPT EXPRESS 16, 2740-2751 (2008); Papagiakoumou, E. et al. Nat Meth 7, 848-854, doi.nature.com/nmeth/journal/v7/n10/abs/nmeth.1505.html #supplementary-information (2010)]. The generalized phase contrast approach can be understood as first patterning a phase-only spatial light modulator (SLM) with a distribution of tiles covering regions corresponding to the object of interest (FIG. 5). The phase-only patterned light passes through a Phase Contrast Filter (PCF). The PCF adds a π phase to the low frequency components (i.e. the light that passes through the inner circle of the PCF) while leaving unchanged the high frequency components of the light (the tiles covering the object) that pass through the outer annulus. The low and high frequency components recombine again in the image plane and interfere.

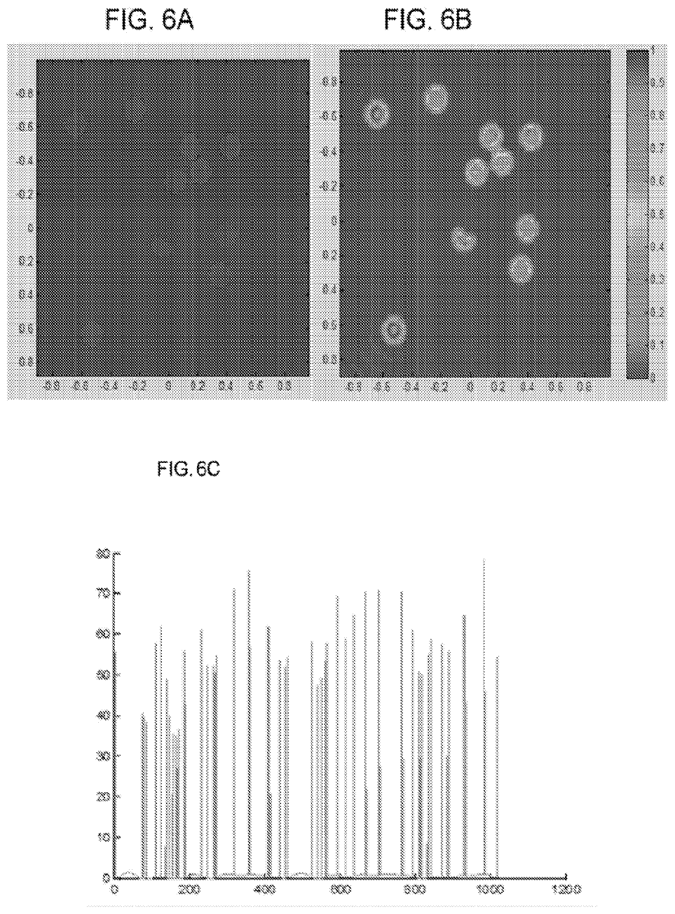

Properly selecting the size of the inner circle aperture ensures the background is dark due to destructive inference, while the areas of interest are bright due to constructive interference. The principles underlying generalized phase contrast patterning are not actually very different from a typical phase contrast microscope. The approach of Gluckstad has an important advantage that, for roughly uniformly distributed objects (tiles), the laser intensity at the background is not lost but is instead added to the locations of the objects. This approach provides a much more efficient use of limited laser power, significantly improving the throughput of wide-field temporal focus patterning. Simulations of phase contrast pattern generation are shown in FIG. 6A-C.

A limitation of the holographic approach is that commonly used twisted-nematic liquid crystals SLMs are slow with update rate typically under 100 Hz (while DMD update rate can reach 30 kHz). This limitation is partly be compensated for by using ferroelectric liquid crystal SLMs that are faster with speed reaching about 5 kHz but they have lower diffraction efficiency and can only provide binary phase control. Low diffraction efficiency is compensated for by using laser with higher pulse energy while binary response may be overcome by grouping multiple pixels within a diffraction-limited area. Each of these embodiments involves trade-offs between laser power, field-of-view, speed, and pattern complexity.

### Example 7

### Online Process Control Based on 3D Phase Imaging

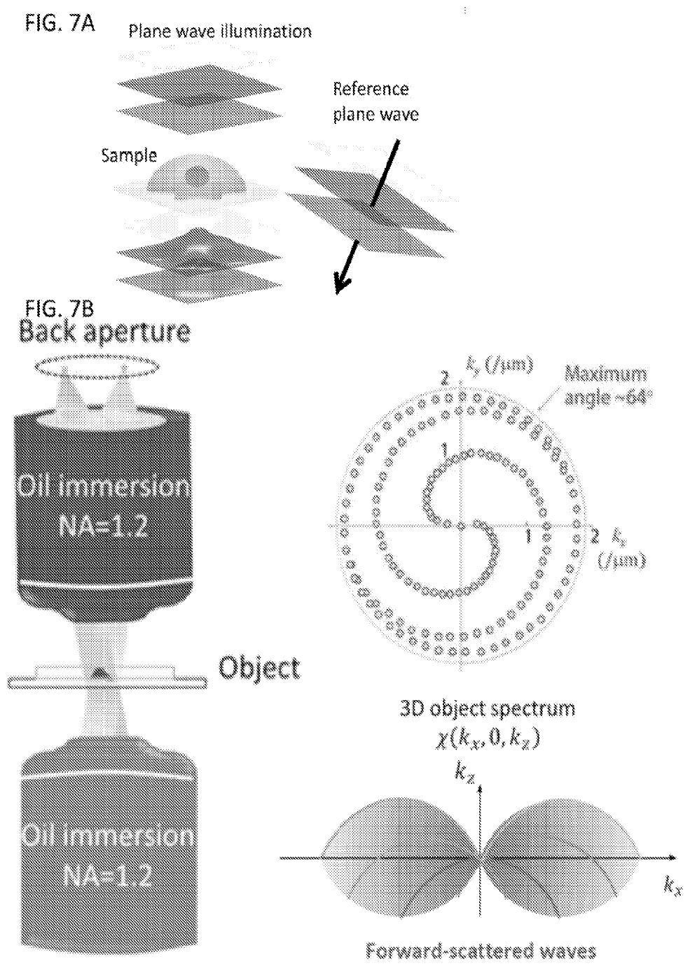

Quantitative phase microscopy (QPM) is utilized to measure the fidelity of ImpFab process. QPM is an interferometric technique used for high-speed mapping of optical path-length delay associated with the refractive index distribution of a target specimen. As shown in FIG. 7A, when coherent light passes through a transparent sample, the wavefront of the transmitted light is modified according to the optical path-length delay, which is directly proportional to the refractive index distribution of the sample. High-speed quantification of the transmitted field is achieved via off-axis holography using a reference field. The measured optical phase is further converted into sample refractive index if the corresponding height or thickness is known and vice versa. It is worth noting that traditional wide-field QPM can only provide average refractive index along the depth due to the lack of depth sectioning. To this end, angle-scan tomographic phase microscopy (TPM), shown in FIG. 7B, helps characterize 3-D refractive index of structures fabricated using line-scan TFTPL. As shown in FIG. 7B, multiple angle-dependent interferograms are acquired. Next, the measured complex optical field maps are re-mapped on the 3D spatial frequency domain based on the optical diffraction theory [Wolf, E. Opt Commun 1, 153-156 (1969)]. Finally, 3D refractive index map is recovered under Rytov or Born approximation [Sung, Y. et al. OPT EXPRESS 17, 266-277, doi:10.1364/oe.17.000266 (2009)].

Previous QPM and TPM methods at best can achieve resolution twice that of coherent diffraction limit and are at least an order of magnitude worse than ImpFab resolution. Therefore, although low spatial resolution features of the fabricated structures are characterized directly, the high-resolution features cannot be directly imaged. However, because the expected structures are known, the resultant images are predicted by using the optical transfer functions of these imaging modalities as a spatial low pass filter. By comparing the expected images with the experimental images, a measure of fidelity is provided even at regions with features beyond phase microscopy resolution. ImpFab is expected to produce very high refractive contrast ˜0.5-1.

Although QPM can easily yield kHz frame rate and match the throughput of line-scan TFTPL, the angle-scan TPM is an inherently slow imaging modality. The highest throughput demonstrated so far is 26 3-D tomograms/sec [Jin, D., et al., OPT EXPRESS 26, 428-437(2018)]. Although it is not critical, sample quality control approach would be best if matching the throughput of line-scan TFTPL. The imaging speed of angle-scan TPM is improved using machine learning based approaches that enable kHz 3-D tomograms/see throughput without sacrificing the spatial resolution or the signal-to-noise ratio (SNR).

### EQUIVALENTS

Although several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto; the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” The phrase “and/or,” as used herein in the specification and in the claims should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified, unless clearly indicated to the contrary.

All references, patents and patent applications and publications cited or referred to in this application are incorporated herein in their entirety herein by reference.

What is claimed is:

1. A method of multi-photon lithography, comprising:
(a) generating a first pulsed light beam having a spectral bandwidth;
(b) expanding the first pulsed light beam to give the first pulsed light beam an elongated cross section;
(c) modulating light pulses of the expanded first pulsed light beam to give one or more of the light pulses an independently selected linear pattern;
(d) dispersing spectral components of the modulated light pulses; and
(e) focusing the dispersed spectral components of the modulated light pulses at an independently selected line in an independently selected focal plane within a target material, wherein the focused spectral components alter the target material within independently selected voxels in the independently selected line, and the independently selected voxels are in spatial correspondence with the independently selected linear pattern.

2-5. (canceled)

6. The method of claim 1, further comprising:
generating a second pulsed light beam and expanding, modulating, dispersing, and focusing the generated second pulsed light beam as in steps (b)-(e), respectively.

7. The method of claim 6, wherein the independently selected linear pattern of the modulated expanded second pulsed light beam is different from the independently selected linear pattern of the modulated expanded first pulsed light beam.

8. The method of claim 6 wherein the dispersed spectral components of the first and second pulsed light beams are focused at different independently selected lines.

9. The method of claim 6, wherein the dispersed spectral components of the first and second pulsed light beams are focused at independently selected lines in different focal planes within the target material.

10. The method of claim 6, further comprising:
directing the first pulsed light beam to a movable reflective component, wherein the movable reflective component causes the dispersed spectral components of the first pulsed light beam to focus at a first independently selected line in the focal plane;
adjusting the movable reflective component; and
directing the second pulsed light beam to the adjusted movable reflective component, wherein the adjusted movable reflective component causes the dispersed spectral components of the second pulsed light beam to focus at a second independently selected line in the focal plane.

11. The method of claim 1, wherein:
modulating the light pulses and dispersing the spectral components of the modulated light pulses are accomplished using a digital micromirror device.

12. The method of claim 1, further comprising:
receiving, at a dichroic mirror, light originating from the specimen; and
directing, using the dichroic mirror, the light to a camera.

13. The method of claim 1, wherein expanding the first pulsed light beam includes:
directing the first pulsed light beam through a first cylindrical lens and a second cylindrical lens, the first and second cylindrical lenses configured to give the first pulsed light beam an elliptical cross section;
directing the elliptical first optical pulse through a first spherical lens and a second spherical lens to transform the elliptical cross section into an expanded elliptical cross section; and
directing the expanded elliptical first optical pulse to a third cylindrical lens to transform the expanded elliptical cross section into the elongated cross section.

14. The method of claim 1, further comprising shrinking the target material.

15. The method of claim 14, wherein the shrinking comprises an Imp/Fab method.

16. A method of multi-photon lithography, comprising:
(a) generating a first pulsed light beam having a spectral bandwidth;
(b) expanding the first pulsed light beam to give the first pulsed light beam an elongated cross section;
(c) splitting the expanded first pulsed light beam into a structured pattern of expanded pulsed light beams;
(d) modulating light pulses of the structured pattern of expanded pulsed light beams to give the light pulses independently selected linear patterns;
(e) dispersing spectral components of the modulated light pulses; and
(f) focusing the dispersed spectral components of the modulated light pulses at independently selected lines in an independently selected focal plane within a target material, wherein the focused spectral components alter the target material within independently selected voxels in the independently selected lines, and the independently selected voxels are in spatial correspondence with the independently selected linear patterns.

17. A system, comprising:
an optical pulse generator configured to generate a first pulsed light beam having a spectral bandwidth;
at least a first optical element configured to expand the first pulsed light beam to give the first pulsed light beam an elongated cross section;
a movable reflective component configured to direct the expanded first pulsed light beam along a first axis;
a digital micromirror device (DMD) configured to:
modulate light pulses of the expanded first pulsed light beam to give the to give one or more of the light pulses an independently selected linear pattern, and
disperse spectral components of the modulated light pulses; and
at least a second optical component configured to focus the dispersed spectral components of the modulated light pulses at an independently selected line in an independently selected focal plane within a target material, wherein the focused spectral components alter the target material within independently selected voxels in the independently selected line, and the independently selected voxels are in spatial correspondence with the independently selected linear pattern.

18. The system of claim 17, further comprising:
a diffractive optical element configured to split the expanded first pulsed light beam into a structured pattern of expanded pulsed light beams, wherein:
the DMD is configured to modulate light pulses of the structured pattern of expanded pulsed light beams to give the light pulses independently selected linear patterns,
the DMD is configured to disperse spectral components of the modulated light pulses, and
the second optical component is configured to focus the dispersed spectral components of the modulated light pulses at independently selected lines in an independently selected focal plane within a target material, wherein the focused spectral components alter the target material within independently selected voxels in the independently selected lines, and the independently selected voxels are in spatial correspondence with the independently selected linear patterns.

19. The system of claim 17, wherein the movable reflective component is a galvanometric scanner.

20. The system of claim 17, further comprising:
a camera configured to monitor a lithographic process within the target material; and
a dichroic mirror configured to direct light originating from the target material towards the camera.

21. The system of claim 17, wherein at least the first optical element comprises:
a first cylindrical lens and a second cylindrical lens, the first and second cylindrical lenses configured to expand the first optical pulse to give the first optical pulse an elliptical cross section;
a first spherical lens and a second spherical lens configured to transform the elliptical cross section into an expanded elliptical cross section; and
a third cylindrical lens configured to transform the expanded elliptical cross section into an elongated cross section focused on the DMD.

22. The system of claim 19, further comprising one or more of: abeam shaper optical component, a spatial light modulator, and a deformable mirror.

23. (canceled)

24. The method of claim 1, further comprising patterning the target material.

25. The method of claim 24, further comprising shrinking the patterned target material, optionally wherein the shrinking comprises an ImpFab method.

26-29. (canceled)
